(19) United States
(12) Patent Application Publication
(10) Pub. No.: US 2024/0011326 A1
(43) Pub. Date: Jan. 11, 2024

(54) ELECTROMECHANICAL LATCH MODULE FOR A DOOR

(71) Applicant: FATH Mechatronics GmbH, Spalt (DE)

(72) Inventors: Peter NETTNER, Heideck (DE); Jürgen SEPT, Röttenbach (DE)

(73) Assignee: FATH Mechatronics GmbH, Spalt (DE)

(21) Appl. No.: 18/347,627

(22) Filed: Jul. 6, 2023

(30) Foreign Application Priority Data
Jul. 6, 2022 (DE) 10 2022 116 915.4

(51) Int. Cl. E05B 47/00; E05B 13/00; H05K 5/02

(52) U.S. Cl. CPC E05B 47/0012; E05B 13/002; H05K 5/0221; E05B 2047/0017; E05B 2047/0023; E05B 2047/0067

(57) ABSTRACT

An electromechanical latch module for a door is provided. Here, all electric or electronic components are situated in an electronics installation space which is encapsulated in a dust-tight and watertight manner and is disposed in a latch housing on the external side of the door. The module is able to be mounted on doors having the two most common hole patterns, and also in combination with a bar lock. An additional external cover for the lock cylinder is not required.

### FIELD

The invention relates to an electromechanical latch module for a door. The invention relates in particular to a pivot lever latch having a pivot lever handle and a mechanism activatable by an electric motor.

### BACKGROUND

Pivot lever latches are in many cases embodied so as to be watertight primarily in applications in security-critical areas, for example for securing server racks. This is necessary in particular also when the pivot lever latches contain components activatable by an electric motor, in order for the functional reliability not to be compromised by the ingress of moisture. Openings on the front side of the latch, for example on a lock cylinder, in this instance have to be sealed with the aid of additional components. For example, lock cylinders are provided with a pivotable or slidable cover. The failure susceptibility of the latch is increased by virtue of these additional movable components. Moreover, covers of this type often are at odds with an ergonomic operation of the latch.

Moreover, owing to the additional requirement in terms of installation space for accommodating the electric and/or electronic components of an electromechanical pivot lever latch, these latches often cannot be universally used. Non-standard mounting openings for mounting such latches are required in some instances, this impeding the easy replacement of latches, in particular the replacement of manually activatable latches by latches activatable by an electric motor. Moreover, known electromechanical pivot lever latches often have disadvantageous ergonomic characteristics.

It is an object of the present invention to provide an ergonomically advantageous pivot lever latch which is activatable by an electric motor and can ideally be universally used. This object is achieved by a latch module as claimed in claim 1. Advantageous embodiments of the invention are set forth in the dependent claims.

### SUMMARY

The electromechanical latch module according to the invention comprises a latch housing which, by way of the lower side thereof, is able to be placed onto one side of the door, thereby preferably covering the external peripheries of one or a plurality of mounting openings provided in the door; a first locking device for locking the door, wherein the first locking device has a pivot lever handle which in the resting position thereof is preferably received in a receptacle of the latch housing; and a second locking device for locking the pivot lever handle, wherein this second locking device has a locking element activatable by an electric motor; wherein parts of the first locking device protrude beyond the lower side of the latch housing so that parts of the first locking device are disposed in a first external installation space within the latch housing as well as in a first internal installation space which is connected to the first external installation space and is on the side of the door that lies opposite the latch housing; and wherein parts of the second locking device protrude beyond the lower side of the latch housing so that parts of the second locking device are disposed in a second external installation space within the latch housing as well as in a second internal installation space which is connected to the second external installation space and is on the side of the door that lies opposite the latch housing; and wherein parts of the second locking device are disposed in a third external installation space within the latch housing, which third external installation space is disposed between the first external installation space and the second external installation space, wherein the parts of the second locking device that are disposed in the third external installation space do not protrude beyond the lower side of the latch housing so that said parts do not require any installation space on the side of the door that lies opposite the latch housing, as a result of which a free space between the first internal installation space and the second internal installation space remains on the side of the door that lies opposite the latch housing, said free space permitting the latch module to be mounted in the case of a door having a single continuous mounting opening, in particular having a rectangular mounting opening with a width of 25 mm and a length of 150 mm, as well as in the case of a door having two mounting openings, in particular having two rectangular mounting openings with a width of 25 mm and a length of 50 mm that are perpendicularly co-aligned and disposed at a mutual spacing of 50 mm.

An ergonomically advantageous pivot lever latch which is activatable by an electric motor and is able to be universally used is provided in this way.

The latch module is particularly suitable for technical cabinets such as server racks, switch boxes and cabinets, for indoors as well as outdoors. Said latch module is able to be used in all areas which have to be secured, such as computer centers, switch boxes on production installations, or in critical infrastructure, for example. Conventional latch modules, in particular latches which are activatable in a purely manual manner, can be easily replaced by the electromechanical latch module according to the invention. The module can be used in combination with various types of locks, in particular with all types of turnbuckle locks with bolts or bars of any type as locking elements.

The invention makes it possible to provide a pivot lever latch in which, with the exception of the sensors optionally disposed in the second locking installation space, substantially all electrical or electronic components of the module are situated in the electronics installation space, thus the third external installation space, which is situated in the latch housing, preferably encapsulated in a dust-tight and watertight manner, and thus on the door external side, thus in front of the door to be locked. Therefore, the module according to the invention, apart from being able to be mounted in a door cut-out of 150 mm×25 mm, not only offers additional compatibility with the mm×25 mm door cut-out variant, both in conjunction with a bar lock, but simultaneously also offers the possibility to dispense with an additional external cover for the lock cylinder for sealing purposes. As a result, not only is the number of movable mechanical components of the module reduced, as a result of which the failure rate is also minimized. Apart from the functional reliability that is enhanced in this way, the front side of the module, in particular the design of the latch housing and of the pivot lever handle, can also be embodied in a particularly ergonomic manner.

According to one preferred embodiment of the invention, parts of the second locking device protrude beyond the lower side of the latch housing so that parts of the second locking device are disposed in a second external installation space within the latch housing as well as in a second internal installation space which is connected to the second external installation space and is on the side of the door that lies opposite the latch housing.

According to one preferred embodiment of the invention, parts of the second locking device are disposed in a third external installation space within the latch housing, which third external installation space is disposed between the first external installation space and the second external installation space. The parts of the second locking device that are disposed in the third external installation space do not protrude beyond the lower side of the latch housing so that said parts do not require any installation space on the side of the door that lies opposite the latch housing, in particular any installation space between the first internal installation space and the second internal installation space. As a result, a free space between the first internal installation space and the second internal installation space remains on the side of the door that lies opposite the latch housing, said free space permitting the latch module to be mounted in the case of a door having a single continuous mounting opening, in particular having a rectangular mounting opening with a width of 25 mm and a length of 150 mm, as well as in the case of a door having two mounting openings, in particular having two rectangular mounting openings with a width of 25 mm and a length of 50 mm that are perpendicularly co-aligned and disposed at a mutual spacing of 50 mm. The two mounting openings permit the first locking installation space, which is formed conjointly by the first external installation space and the first internal installation space, as well as the second locking installation space, which is formed conjointly by the second external installation space and the second internal installation space, to be received in the door, or the corresponding installation spaces to be routed through the door, respectively.

According to one preferred embodiment of the invention, all three installation spaces, thus the first locking installation space, second locking installation space, as well as the electronics installation space, are embodied as self-contained spaces. The two locking installation spaces here extend on both sides of the door. The electronics installation space is disposed exclusively in the latch housing, i.e. on the door external side.

According to one preferred embodiment of the invention, the only connection between the second locking installation space and the spatial volume on the inside of the door exists by virtue of the connecting cable which is routed out of the second locking installation space through the cover.

According to one preferred embodiment of the invention, the only connection between the first locking installation space and the spatial volume on the inside of the door exists by virtue of the latching pin of the first locking device, which is routed out of the first locking installation space through the turnbuckle housing. The latching pin is preferably also sealed in order to meet the desired protection code (e.g. IP65).

According to one preferred embodiment of the invention, the second locking device has a lock cylinder which is fixedly established on the pivot lever handle so as to be close to the free end of the pivot lever handle and has a movable, rotatable locking cam that can assume various rotary positions, including a latched position and at least one opened position different from the latched position. With the aid of this lock cylinder, the pivot lever at the free end thereof is able to be locked in the latch housing.

According to one preferred embodiment of the invention, at least one sensor for determining the locking state of the lock cylinder, in particular for determining whether the locking cam of the lock cylinder is situated in a latched position, or for determining whether the locking cam is situated in an opened position, is provided. This sensor is preferably situated in the second external installation space. The sensor is advantageously an optical sensor. An embodiment in which the sensor, preferably conjointly with a sensor circuit board on which the sensor is situated, is cast in a suitable casing material and thus sealed in a watertight manner, the casing material being transparent for the purpose of the optical sensor, has proven particularly advantageous. Any other suitable sensor such as, for example, a Hall sensor, can also be used instead of an optical sensor.

According to one preferred embodiment of the invention, the latch module is embodied in such a manner that the pivot lever handle can be returned to its resting position, even when the latch slide has been automatically moved back to its locking position immediately after unlocking the first latch device for security reasons. In this way, the pivot lever handle can always be moved to its resting position independently of the manner in which the lock has been opened.

According to one preferred embodiment of the invention, when folding the pivot lever handle into its resting position, the latch slide, by impingement with the locking cam of the lock cylinder, is movable—counter to the force of a spring element acting on the latch slide—from its locking position to a transitional position, which is different from the releasing position, in which transitional position the latch slide does not block the pivot lever handle from being folded into the resting position thereof. Owing to the spring element, the latch slide subsequently automatically assumes its blocking position when the pivot handle lever is in its resting position. In other words, a movement of the latch slide from its blocking position takes place in that the locking cam of the lock cylinder forces the latch slide out of its blocking position when the handle is folded in, such that the latch slide moves beyond the locking cam and automatically re-assumes its blocking position as soon as the pivot lever handle is in the resting position.

According to one preferred embodiment of the invention, the second external installation space is sealed in relation to the third external installation space. At the same time, the second internal installation space is sealed in relation to the remaining spatial volume on the side of the door that lies opposite the latch housing. Both seals correspond at least to protection code IP54, preferably protection code IP65. In this way, moisture which enters the second locking installation space formed by the second external installation space and the second internal installation space through the lock cylinder can invade neither the spatial volume behind the door nor the third external installation space, serving as the electronics installation space.

### DESCRIPTION OF THE FIGURES

Further advantageous embodiments of the invention will be explained in more detail hereunder in conjunction with an exemplary embodiment of the invention and by means of the drawings, in which:

FIG. 1 shows a latch module having a folded-out and pivoted handle;

FIG. 2 shows the latch module from the front;

FIG. 3 shows the latch module from the side;

FIG. 4 shows the latch module from the rear (closed);

FIG. 5 shows the latch module from the rear (without covers);

FIG. 6 shows the latch module in an exploded illustration;

FIG. 7 shows a sectional illustration of the latch module along the line AA in FIG. 4;

FIG. 8 shows the handle from the front;

FIG. 9 shows the handle from the side;

FIG. 10 shows the handle in an exploded illustration;

FIG. 11 shows the electromechanical unit from the front;

FIG. 12 shows the electromechanical unit from the side; and

FIG. 13 shows the electromechanical unit in an exploded illustration.

### DETAILED DESCRIPTION

In all of the figures, the invention is shown not true to scale, only schematically and only with its essential component parts. The same reference signs here refer to elements of identical or equivalent function.

Spatial indicators such as “front” or “rear”, or “top” or “bottom”, respectively, refer to the state of the latch when used as intended, or as is illustrated in the figures, respectively.

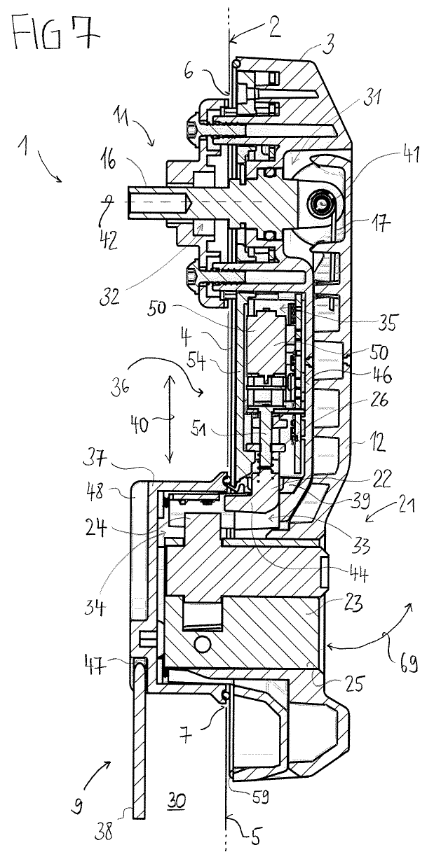

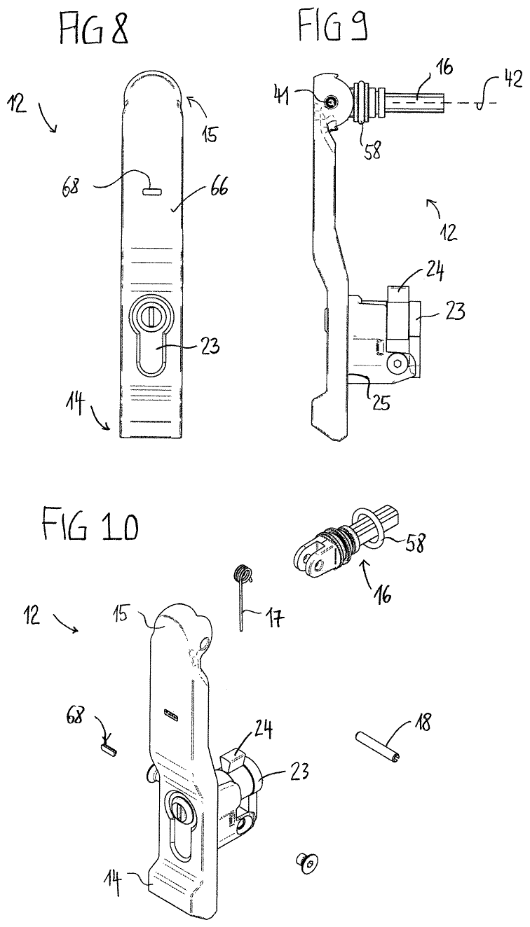

The electromechanical latch module 1 according to the invention serves for locking a door 2, for example the door 2 of a server rack. The latch module 1 comprises a latch housing 3, which, by way of its lower side 4, is able to be placed on a side 5 of the door 2, here on a door leaf, using an annular seal 59, thereby preferably covering the external peripheries of one or a plurality of mounting openings 6, 7 provided in the door 2. The door leaf is merely implied in FIG. 7. Said door leaf has two standard mounting openings 6, 7 with the dimensions 50 mm×25 mm. However, the module 1 is also able to be mounted on doors with a single standard mounting opening of mm×150 mm and is thus compatible with the two most common hole patterns.

The latch module 1 comprises a first locking device 11 for locking the door 2, wherein the first locking device 11 has a pivot lever handle 12 which in the resting position thereof is received in a receptacle 13 of the latch housing 3.

The latch module 1 comprises a second locking device 21 for locking the pivot lever handle 12, wherein this second locking device 21 has a locking element 22 activatable by an electric motor.

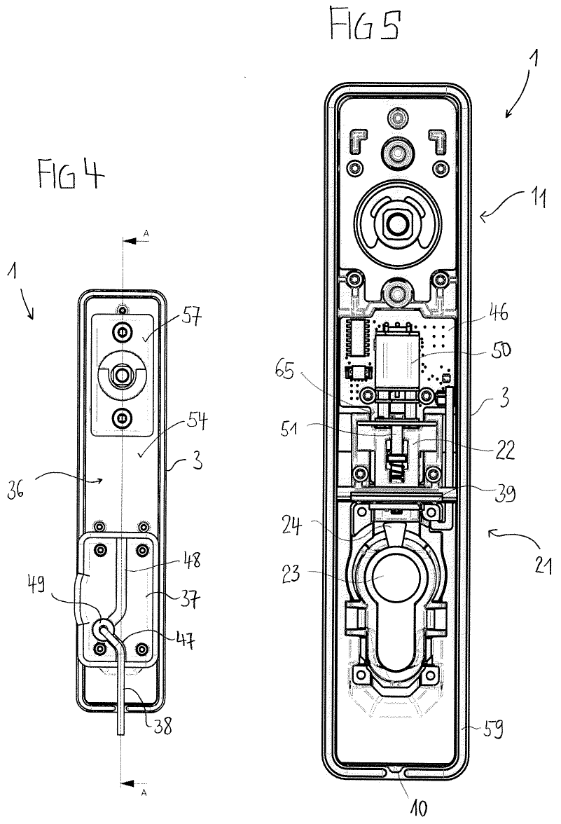

Parts of the first locking device 11 protrude beyond the lower side 4 of the latch housing 3 so that parts of the first locking device 11 are disposed in a first external installation space 31 within the latch housing 3 as well as in a first internal installation space 32 which is connected to the first external installation space 31 and is on the side 30 of the door 2 that lies opposite the latch housing 3, cf. FIG. 3.

Parts of the second locking device 21 protrude beyond the lower side 4 of the latch housing 3 so that parts of the second locking device 21 are disposed in a second external installation space 33 within the latch housing 3 as well as in a second internal installation space 34 which is connected to the second external installation space 33 and is on the side 30 of the door 2 that lies opposite the latch housing 3.

Parts of the second locking device 21 are disposed in a third external installation space 35 within the latch housing 3, which third external installation space 35 is disposed between the first external installation space 31 and the second external installation space 32. The parts of the second locking device 21 that are disposed in the third external installation space 35 do not protrude beyond the lower side 4 of the latch housing 3 so that said parts do not require any installation space on the side 30 of the door 2 that lies opposite the latch housing 3, in particular any installation space between the first internal installation space 32 and the second internal installation space 34. As a result, a free space 36 between the first internal installation space 32 and the second internal installation space 34 remains on the side 30 of the door 2 that lies opposite the latch housing 3, said free space 36 permitting the latch module 1 to be mounted in the case of a door 2 having a single continuous mounting opening (not illustrated), in particular having a rectangular mounting opening with a width of 25 mm and a length of 150 mm, as well as in the case of a door 2 having two mounting openings 6, 7, in particular having two rectangular mounting openings 6, 7 with a width of 25 mm and a length of 50 mm that are perpendicularly co-aligned and disposed at a mutual spacing of 50 mm. The two mounting openings 6, 7 permit the first locking installation space, which is formed conjointly by the first external installation space 31 and the first internal installation space 32, as well as the second locking installation space, which is formed conjointly by the second external installation space 33 and the second internal installation space 34, to be received in the door 2, or the corresponding installation spaces to be routed through the door 2, respectively.

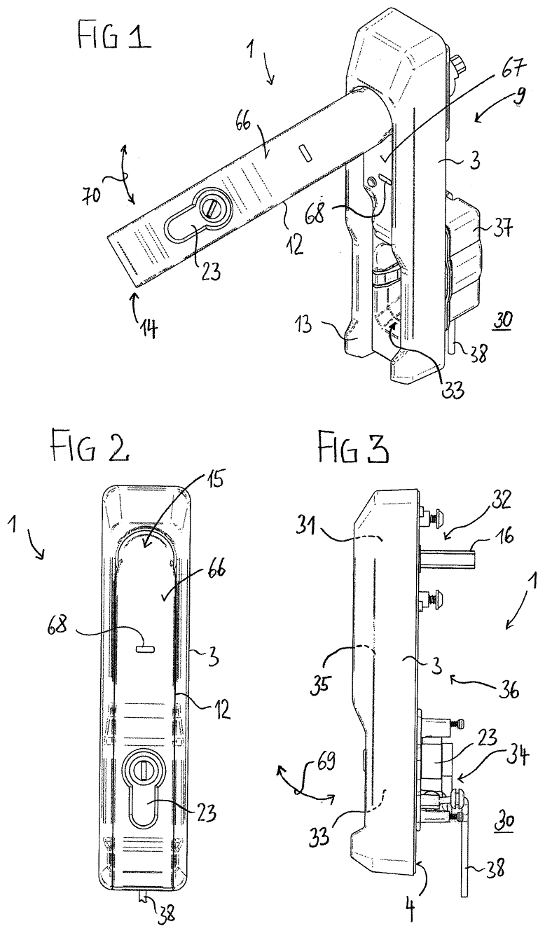

For unlocking the door 2, the pivot lever handle 12 of the first locking device 11 is able to be folded out of a resting position away from the latch housing 3 to a pivoting position and, in this pivoting position, is pivotable from a locking position to an unlocking position and back. The inward and outward folding direction 69 about the pivot axis 41 is indicated in FIG. 3; the pivoting direction 70 about the pivot axis 42 is indicated in FIGS. 1 and 6.

The first locking device 11 comprises a latching pin 16. For example, a latch tongue (not illustrated), or else a pinion (not illustrated) for driving a rack or a toothed locking bar of a bar lock, is fastened in a rotationally fixed manner to the latching pin 16. The latch tongue can be embodied such that, in the locking position of the handle 12, it lies behind a chamfer (not illustrated) of the door frame and as a result firmly holds the door leaf.

The latching pin 16, with the use of a suitable spring element 17, is fixed to the fixed end 15 of the handle 12 with the aid of a dowel pin 18, wherein the dowel pin 18 simultaneously defines the first pivot axis 41 of the handle 12 relative to the latching pin 16, such that the handle 12 is pivotably articulated on the latching pin 16. In this way, the handle 12 can be folded out of its resting position in the receptacle 13 of the housing 3 to its pivoted position and folded back in again. In the pivoted position of said handle 12, the latching pin 16, and conjointly with the latter the latching tongue or the like fastened therein, is then pivotable about a second pivot axis 42 which is perpendicular to the first pivot axis 41 and is defined by the central longitudinal axis of the latching pin 16, by virtue of the handle 12 being pivoted between a locking position and an unlocking position as is shown in FIG. 1. Depicted in FIG. 6 is a retaining disk 19 which keeps the handle 12 in the housing 3.

The second locking device 21 has a lock cylinder 23 which is fixedly established on the pivot lever handle 12 so as to be close to the free end 14 of the pivot lever handle 12 and has a movable, rotatable locking cam 24 that can assume various rotary positions, including a latched position and at least one opened position different from the latched position. With the aid of this lock cylinder, the pivot lever 12, at the free end 14 thereof, is able to be locked in the latch housing 3. The lock cylinder 23 is preferably a profile cylinder, in particular a DIN 10/30 profile half-cylinder.

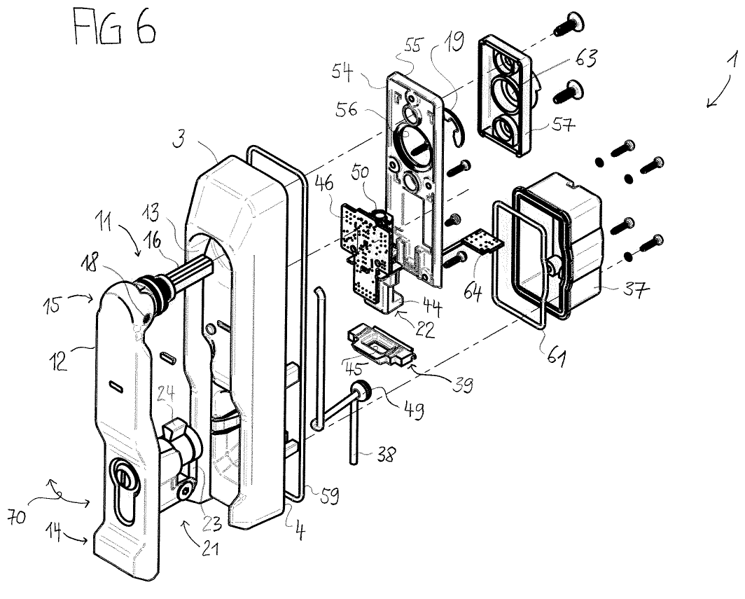

The locking element 22 of the second locking device 21 in the example illustrated is embodied as a latch slide which is movable from a blocking position to a releasing position and back and, in the blocking position thereof, mechanically blocks the pivot lever handle 12 from being folded out of the resting position thereof when the locking cam 24 of the lock cylinder 23 is disposed in the latched position. FIGS. 5 and 7 show the releasing position of the latch slide 22.

The handle 12 has a holder 25 for the lock cylinder 23. The lock cylinder 23 attached to the handle 12 is folded out by means of the handle 12 and also pivoted and folded back into the resting position. When folding out the handle 12 to the pivoted position thereof, the lock cylinder 23 is completely guided out of the second locking installation space. Conversely, when folding in the handle 12 into the receptacle 13 of the latch housing 3, the locks cylinder 23 is re-introduced into the second locking installation space, wherein, in the resting position of the handle 12, the front part of the lock cylinder 23 is disposed in the second external installation space 33, and the rear part is disposed in the second internal installation space 34.

The latch slide 22, by way of the one, upper end 28 thereof, is disposed in the third external installation space 35 and in the latter interacts with a driver 26 in the form of a nut which is disposed on the motor shaft 51 and, in a corresponding recess 27 of the latch slide 22, is linearly displaced so as to bear on the latch slide 22. The opposite, lower end 29 of the latch slide 22 is configured L-shaped in the manner of a foot, wherein the end face 43 of the projection 44 serves as a detent for the locking cam 24 of the lock cylinder 23 and thus for implementing the locking function. While the main body 53 of the latch slide 22, which extends in the displacement direction 40, is situated in the external installation spaces 33, 35, the projection 44 extends out of the second external installation space 33 into the second internal installation space 34.

The second external installation space 33 is sealed in relation to the third external installation space 35. At the same time, the second internal installation space 34 is sealed in relation to the remaining spatial volume 9 on the side 30 of the door 2 that lies opposite the latch housing 3. Both seals correspond to protection code IP54, preferably protection code IP65. In this way, moisture which enters the second locking installation space formed by the second external installation space 33 and the second internal installation space 34 through the lock cylinder 23 can invade neither the spatial volume 9 behind the door 2 nor the third external installation space 35, serving as the electronics installation space. Water that has entered the second locking installation space through the lock cylinder 23 can exit the module 1 again through an opening 10 provided on the lower side of the second external installation space 33.

For the purpose of sealing as described, the second internal installation space 34 is covered by a cover 37 which encapsulates the second internal installation space 34 in relation to the remaining spatial volume 9 on the side 30 of the door 2 that lies opposite the latch housing 3. This cover 37, which is sealed with the aid of a further annular seal 61, is embodied asymmetrically in such a manner that the bars of a bar lock can be guided past the cover 37 on one side, depending on the arrangement. To this end, the cover 37 can be mounted in two orientations, i.e. rotated by 180°. The cover 37 has various cable routings 47, 48, so that the connecting cable 38 can be routed away toward the top as well as the bottom through a feedthrough grommet 49 which seals the cover 37 in relation to the outside. The cable routing 47, 48 simultaneously serves as a strain relief for the connecting cable 38.

For the purpose of sealing as described, a sealing element 39 which provides a sealing passage for at least part of the second locking device 21, in particular for the latch slide 22, is disposed between the second external installation space 33 and the third external installation space 35. In other words, the latch slide 22 is disposed in the second external installation space 33 as well as in the third external installation space 35. Said latch slide 22 extends through an opening 45 of the sealing element 39, from one installation space to the other.

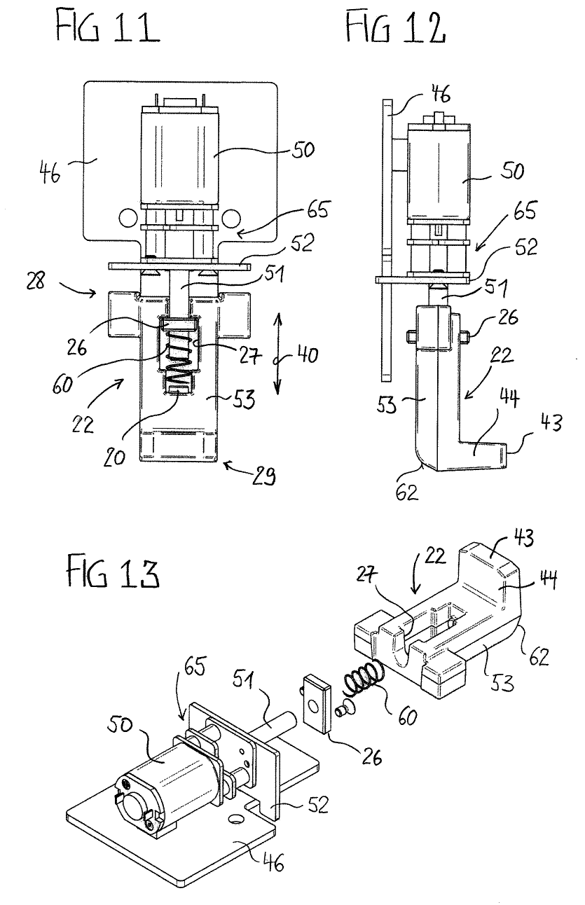

The second locking device 21 comprises an electric motor 50 which is actuatable by a controller (not illustrated) outside the latch module 1 and is disposed in the third external installation space 35. The motor fastening plate 52 is illustrated in FIGS. 11 to 13. The actuation is performed in particular with the aid of control signals which are transmitted from the controller to a motor circuit board 46 assigned to the electric motor 50. The motor shaft 51, for converting the rotating movement of the shaft into a linear movement of the latch slide 22, is provided with an external thread (not illustrated), as a result of which the nut 26 that is provided with an internal thread (not illustrated) and interacts with the motor shaft 51 is movable, said nut 26 acting as a driver for moving the latch slide 22 from the blocking position to the releasing position.

Due to the very limited installation space, the DC motor 50 fitted in the electronics installation space 35 is provided with a particularly compact gear mechanism, which here is configured as a spur gear mechanism 65.

The first external installation space 31 and the third external installation space 35 are closed with the aid of a common rear cover 54, the external side 55 thereof being directed toward that side 5 of the door 2 on which the latch housing 3 is placed by way of the lower side 4 thereof. While the rear cover 55 tightly closes the third external installation space 35, said rear cover 55 has, in the region of the first external installation space 31, the openings required for the functioning of the first locking device 11, in particular an opening 56 for passing through the latching pin 16. The first external installation space 31 and the first internal installation space 32 in this way conjointly form the first locking installation space. The first internal installation space 32 is covered by a cover 57 which encapsulates the first internal installation space 32 in relation to the remaining spatial volume 9 on the side 30 of the door 2 that lies opposite the latch housing 3. The cover 57 in the example shown here is embodied as a turnbuckle housing. The cover 57 in turn has an opening 63 for passing through the latching pin 16.

In this way, all three installation spaces, thus the first locking installation space 31, 32, the second locking installation space 33, 34, as well as the electronics installation space 35, are embodied as self-contained spaces. The two locking installation spaces here extend on both sides of the door 2. The electronics installation space 35 is disposed exclusively in the latch housing 3, i.e. on the door external side 5.

The only connection between the second locking installation space 33, 34 and the spatial volume 9 on the inside of the door exists by virtue of the connecting cable 38 which is routed out of the second locking installation space through the cover 37.

The only connection between the first locking installation space 31, 32 and the spatial volume 9 on the inside of the door exists by virtue of the latching pin 16 of the first locking device 11, which is routed out of the first locking installation space through the turnbuckle housing 57. The latching pin 16 is also sealed in order to meet the desired protection code (e.g. IP65). A sealing element 58 in the form of an O-ring serves as a seal here.

The latch slide 22, when folding in the pivot lever handle 12 to the resting position thereof, is movable—counter to the force of a spring element 60 acting on the latch slide 22—out of its blocking position to a transitional position, different from the releasing position, by impingement by the locking cam 24 of the lock cylinder 23, in which transitional position the latch slide 22 does not block the pivot lever handle 12 from folding into the resting position of the latter. Owing to the spring element 60, the latch slide 22 subsequently automatically assumes its blocking position when the pivot handle lever 12 is in its resting position. In other words, a movement of the latch slide 22 from its blocking position takes place in that the locking cam 24 of the lock cylinder 23 forces the latch slide 22 out of its blocking position when the handle 12 is folded in, such that the latch slide 22 moves beyond the locking cam 24 and automatically re-assumes its blocking position as soon as the pivot lever handle 12 is in the resting position. In this way, the pivot lever handle 12 can be returned to its resting position, even when the latch slide 22 has been automatically moved back to its blocking position immediately after unlocking the first latch device 21 for security reasons. In this way, the pivot lever handle 12 can always be moved to its resting position independently of the manner in which the lock has been opened.

The restoring spring 60 by which the latch slide 22 has been returned from its transitional position back to its blocking position in order to implement the latching function described is embodied here as a coil compression spring which is fitted over the motor shaft 51 and, by way of the one spring end thereof, is supported on the nut 26 and, by way of the other spring end thereof, is supported on the latch slide 22, for which purpose a spring dome is provided on the latter.

In order to facilitate the movement of the latch slide 22 from the blocking position to the transitional position, the latch slide 22, on the external lower edge thereof, has a ramp 62 for the locking cam 24.

A sensor which, for determining the locking state of the lock cylinder 23, in particular for determining whether the locking cam 24 is situated in the latched position, or for determining whether the locking cam 24 is in an opened position, is disposed in the second external installation space 33, so as to be close to the locking cam 24.

An optical sensor is preferably used as the sensor, which is situated on a sensor circuit board 64 that is pushed into a suitable bracket in the interior of the second external installation space 33. The circuit board 64 of the sensor is cast in a suitable casing material and thus sealed in a watertight manner, said casing material being transparent for the purpose of the optical sensor. For connecting the sensor circuit board 64 to the main circuit board 46 in the electronics installation space 35, a flexible part of the circuit board 64 is guided through a sealing element which separates the second external installation space 33 from the third external installation space 35. This here may be the sealing element 39 which also has the passage for the latch slide 22.

A sensor (not depicted) for determining the state of the locking element 22, in particular for determining whether the locking element 22 is situated in its blocking position, is optionally also disposed in the second external installation space 33.

The sensor for the position of the locking cam 24 as well as the sensor for the position of the latch slide 22 are suitably sealed, in particular in relation to moisture. The transmission of the sensor data to the circuit board 46 and/or to the controller for the purpose of monitoring the status and the functioning of the latch and its components preferably takes place with the aid of a cable 38 which is suitably connected within the latch module 1 and routed out of the latch module 1. This is preferably the only connecting cable of the module 1, in particular in the form of a combined current and data cable which simultaneously supplies the module 1 with power by way of a connection to an external current supply (e.g. 10 Volt or 24 Volt). The cable 38 is routed from the third external installation space 35 into the second external installation space 33, and from the second external installation space 33 by way of the second internal installation space 34 through the cover 37 routed into the spatial volume 9 on the side 30 of the door 2 that lies opposite the latch housing 3.

Optical displays 68, here in the form of LEDs for displaying the status or the functioning of the module 1 or the lock, respectively, which, for transmitting signals, are connected to the circuit board 46, are advantageously provided on the external side 66 of the pivot lever handle 12, and on the front wall 67 of the third external installation space 35 that is disposed in the receptacle 13 of the latch housing 3.

All of the features illustrated in the description, in the claims hereunder and the drawings can be relevant to the invention individually as well is in any arbitrary combination with one another. These features, or combinations of features, can each respectively substantiate an independent invention, the claiming of which is expressly reserved.

When a combination of features defining an invention is specified, it is not imperatively necessary to combine individual features from the description of an exemplary embodiment with one or more or all other features specified in the description of this exemplary embodiment; in this respect, any sub-combination of features of one or more exemplary embodiments is expressly also disclosed.

Moreover, substantive features of the apparatus may be used as method features when reworded, and method features may be used as substantive features of the apparatus when reworded. In this way, reworded features are implicitly also disclosed.

### LIST OF REFERENCE SIGNS

1 Latch module
2 Door
3 Latch housing
4 Housing lower side
5 Door external side
6 First mounting opening 25×50 mm
7 Second mounting opening 25×50 mm
8 Door internal side
9 Spatial volume
10 Exit opening
11 First locking device
12 Pivot lever handle
13 Receptacle
14 Free end of the handle
15 Fixed end of the handle
16 Latching pin
17 Spring element
18 Dowel pin
19 Retaining disk
20 Spring dome
21 Second locking device
22 Locking element, latch slide
23 Lock cylinder
24 Locking cam
25 Holder
26 Driver, nut
27 Recess
28 Upper latch slide end
29 Lower latch slide end
30 Opposite side of the door
31 First external installation space
32 First internal installation space
33 Second external installation space
34 Second internal installation space
35 Third external installation space
36 Free space
37 Cover
38 Connecting cable
39 Sealing element
40 Displacement direction
41 First pivot axis
42 Second pivot axis
43 End face
44 Projection
45 Sealing element opening
46 Motor circuit board, main circuit board
47 Cable routing
48 Cable routing
49 Feedthrough grommet
50 Motor
51 Motor shaft
52 Motor fastening plate
53 Main body
54 Rear cover
55 External side
56 Feedthrough opening
57 Cover, turnbuckle housing
58 Sealing element, O-ring
59 Annular seal
60 Spring element
61 Annular seal
62 Ramp
63 Feedthrough opening
64 Sensor circuit board
65 Gear mechanism
66 Handle external side
67 Front wall
68 LED
69 Inward and outward folding direction
70 Pivoting direction

1. An electromechanical latch module for a door,
having a latch housing which, by way of the lower side thereof, is able to be placed on one side of the door;
having a first locking device for locking the door, wherein the first locking device has a pivot lever handle; and
having a second locking device for locking the pivot lever handle, wherein this second locking device has a locking element activatable by an electric motor;
wherein parts of the first locking device protrude beyond the lower side of the latch housing so that parts of the first locking device are disposed in a first external installation space within the latch housing as well as in a first internal installation space which is connected to the first external installation space and is on the side of the door that lies opposite the latch housing;
wherein parts of the second locking device protrude beyond the lower side of the latch housing so that parts of the second locking device are disposed in a second external installation space within the latch housing as well as in a second internal installation space which is connected to the second external installation space and is on the side of the door that lies opposite the latch housing;
wherein parts of the second locking device are disposed in a third external installation space within the latch housing, which third external installation space is disposed between the first external installation space and the second external installation space, wherein the parts of the second locking device that are disposed in the third external installation space do not protrude beyond the lower side of the latch housing so that said parts do not require any installation space on the side of the door that lies opposite the latch housing, as a result of which a free space between the first internal installation space and the second internal installation space remains on the side of the door that lies opposite the latch housing, said free space permitting the latch module to be mounted in the case of a door having a single continuous mounting opening as well as in the case of a door having two mounting openings.

2. The latch module as claimed in claim 1,
wherein the pivot lever handle of the first locking device for unlocking the door is able to be folded out of a resting position away from the latch housing to a pivoting position and, in this pivoting position, is pivotable from a locking position to an unlocking position and back; and
wherein the second locking device has a lock cylinder which is fixedly established on the pivot handle lever and has a movable locking cam that can assume a latched position and an opened position, different from the latched position; and
wherein the locking element is a latch slide which is movable from a blocking position to a releasing position and back, and, in the blocking position, mechanically blocks the pivot lever handle from being folded out of the resting position thereof when the locking cam of the lock cylinder is disposed in the latched position.

3. The latch module as claimed in claim 1, wherein the second external installation space is sealed in relation to the third external installation space.

4. The latch module as claimed in claim 1, wherein the second internal installation space is sealed in relation to the remaining spatial volume on the side of the door that lies opposite the latch housing.

5. The latch module as claimed in claim 4, wherein the second internal installation space is covered by a cover which encapsulates the second internal installation space in relation to the remaining spatial volume on the side of the door that lies opposite the latch housing.

6. The latch module as claimed in claim 3, wherein a sealing element which provides a sealed passage for at least part of the second locking device is disposed between the second external installation space and the third external installation space.

7. The latch module as claimed in claim 1, wherein the second locking device comprises an electric motor and is disposed in the third external installation space, wherein the motor shaft of the motor is provided with an external thread, as a result of which a driver that is provided with an internal thread and interacts with the motor shaft is movable so as to move the locking element.

8. The latch module as claimed in claim 2, wherein the locking element, when folding in the pivot lever handle to the resting position thereof, is movable out of its blocking position to a transitional position by impingement by the locking cam of the lock cylinder, in which transitional position the locking element does not block the movement of the pivot lever handle to the resting position of the latter and the locking element automatically assumes its blocking position when the pivot lever handle is in its resting position.

9. The latch module as claimed in claim 2, having a sensor for determining the locking state of the lock cylinder, said sensor being disposed in the second external installation space.

10. The latch module as claimed in claim 2, having a sensor for determining the state of the locking element, said sensor being disposed in the second external installation space.

11. The latch module as claimed in claim 1, wherein the first locking device is configured to selectively connect to a locking element in the form of a bolt or a bar.

12. The latch module as claimed in claim 1, wherein the latch housing covering the external peripheries of one or a plurality of mounting openings provided in the door if being placed on the one side of the door.

13. The latch module as claimed in claim 1, wherein the pivot lever handle in the resting position thereof is received in a receptacle of the latch housing.

14. The latch module as claimed in claim 1, wherein if said free space permitting the latch module to be mounted in the case of a door having a single continuous mounting opening, said single continuous mounting opening being a rectangular mounting opening with a width of 25 mm and a length of 150 mm.

15. The latch module as claimed in claim 1, wherein if said free space permitting the latch module to be mounted in the case of a door having two mounting openings, said two mounting openings being two rectangular mounting openings with a width of 25 mm and a length of 50 mm that are perpendicularly co-aligned and disposed at a mutual spacing of 50 mm.

16. The latch module as claimed in claim 3, wherein the provided seal corresponds to protection code IP54 or better, preferably to protection code IP65.

17. The latch module as claimed in claim 4, wherein the provided seal corresponds to protection code IP54 or better, preferably to protection code IP65.

18. The latch module as claimed in claim 6, wherein the sealing element provides a sealed passage for the locking element.

19. The latch module as claimed in claim 7, wherein the electric motor is actuatable by a controller outside the latch module.

20. The latch module as claimed in claim 9, wherein said sensor is adapted for determining whether the locking cam is in the latched position, or for determining whether the locking cam is in an opened position.

21. The latch module as claimed in claim 10, wherein said sensor is adapted for determining whether the locking element is in its blocking position.
